(19) United States
(12) Patent Application Publication
(10) Pub. No.: US 2005/0000445 A1
(43) Pub. Date: Jan. 6, 2005

(54) Plasma processing device and plasma processing method

(75) Inventor: Nobuo Ishii, Hyogo (JP)

Correspondence Address: Finnegan, Henderson, Farabow,;Garrett & Dunner, L.L.P., 1300 I Street, N.W., Washington, DC, 20005-3315, US

(73) Assignee: TOKYO ELECTRON LIMITED

(21) Appl. No.: 10/836,268

(22) Filed: May 3, 2004

(30) Foreign Application Priority Data
May 7, 2003 (JP) 128860/2003

(51) Int. Cl. C23C 16/00

(52) U.S. Cl. 118/723 MW

(57) ABSTRACT

A plasma processing device includes a susceptor, processing vessel, dielectric plate, antenna, and projection. The susceptor has a stage surface on which a target object is to be arranged. The processing vessel accommodates the susceptor and has an opening in a side which opposes the stage surface of the susceptor. The dielectric plate closes the opening of the processing vessel. The antenna supplies a high-frequency electromagnetic field into the processing vessel through the dielectric plate. The projection projects from a surface of the antenna which opposes the dielectric plate toward the dielectric plate. The projection is conductive at least at its surface. A plasma processing method is also disclosed.

### BACKGROUND OF THE INVENTION

The present invention relates to a plasma processing device and method and, more particularly, to a plasma processing device and method that generate a plasma by using a high-frequency electromagnetic field and process a target object such as a semiconductor, LCD (liquid crystal display), or organic EL (electro luminance panel).

In the manufacture of a semiconductor device and flat panel display, plasma processing devices are used often to perform processes such as formation of an insulating film, crystal growth of a semiconductor layer, etching, and ashing. Among the plasma processing devices, a high-frequency plasma processing device is available which supplies a high-frequency electromagnetic field into a processing vessel, and ionizes, excites, and dissociates a gas in the processing vessel, thus generating a plasma. The high-frequency plasma processing device can perform a plasma process efficiently since it can generate a low-pressure, high-density plasma.

FIG. 13 shows the overall arrangement of a conventional high-frequency plasma processing device. The plasma processing device has a processing vessel 101 with an upper opening. A susceptor 102 for placing a substrate W thereon is fixed to the central portion of the bottom surface of the processing vessel 101. Exhaust ports 105 for vacuum evacuation are formed in the periphery of the bottom surface of the processing vessel 101. A gas introducing nozzle 106 is arranged in the side wall of the processing vessel 101 to introduce a gas into the processing vessel 101. The upper opening of the processing vessel 101 is closed with a dielectric plate 107. A flat antenna 120 is disposed on the dielectric plate 107. The flat antenna 120 is connected to a high-frequency power supply 111 through a waveguide 114.

The high-frequency electromagnetic field generated by the high-frequency power supply 111 is supplied into the processing vessel 101 through the waveguide 114 and flat antenna 120. In the processing vessel 101, the gas introduced from the nozzle 106 is ionized or dissociated by the supplied high-frequency electromagnetic field. Thus, a plasma is generated to process the substrate W (for example, see Japanese Patent Laid-Open No. 2002-217187).

FIG. 14 is a graph showing the distribution of the density of a plasma P which is generated using the conventional plasma processing device shown in FIG. 13 by setting the pressure in the processing vessel 101 to 113 Pa and supply power to 2.5 kW. The axis of abscissa represents a distance r from the center within a plane parallel to the stage surface of the susceptor 102, and the axis of ordinate represents a value (Is/Ismax) obtained by normalizing a saturation electron current Is at a plasma space potential with its maximal value Ismax. As the saturation electron current Is is proportional to an electron density Ne in the plasma, i.e., the plasma density, FIG. 14 substantially coincides with the distribution of the plasma density. It is apparent from FIG. 14 that in the conventional plasma processing device, the plasma density is high at the central portion, and decreases toward the periphery.

In the process for the substrate W utilizing the plasma P, the distribution of the plasma density within a plane parallel to the substrate W influences the processing speed. More specifically, as shown in FIG. 14, when the distribution of the plasma density is nonuniform, the processing speed decreases at the periphery where the plasma density is lower than at the central portion, and the entire surface of the substrate W cannot be uniformly processed within a predetermined period of time. In this case, the distribution of the plasma density must be adjusted to be more uniform.

### SUMMARY OF THE INVENTION

The present invention has been made to solve the above problem, and has as its object to enable adjustment of the distribution of the plasma density.

In order to achieve the above object, a plasma processing device according to the present invention comprises a susceptor having a stage surface on which a target object is to be arranged, a vessel which accommodates the susceptor and has an opening in a side which opposes the stage surface of the susceptor, a dielectric plate which closes the opening of the vessel, an antenna which supplies a high-frequency electromagnetic field into the vessel through the dielectric plate, and a projection which projects from a surface of the antenna which opposes the dielectric plate toward the dielectric plate, the projection being conductive at least on a surface thereof.

A plasma processing method according to the present invention comprises the steps of arranging a target object in a vessel, supplying a high-frequency electromagnetic field with an antenna into the vessel from outside through a dielectric plate which closes an opening of the vessel, thus generating a plasma in the vessel, the antenna including a projection which projects from a surface thereof toward the dielectric plate, and the projection being conductive at least on a surface thereof, and subjecting the target object to a predetermined process with the plasma.

### BRIEF DESCRIPTION OF THE DRAWINGS

FIG. 1 is a view showing the overall arrangement of a plasma processing device according to the first embodiment of the present invention;

FIG. 2 is a plan view showing the antenna surface of a radial line slot antenna (to be abbreviated as RLSA hereinafter) in FIG. 1;

FIG. 3A is a plan view showing an example of the shape and size of a concave member;

FIG. 3B is a sectional view taken along the line IIIB-IIIB′ of FIG. 3A;

FIG. 4 is a graph showing 0th-order type-I Bessel function;

FIG. 5 is a graph showing the distribution of a plasma density in the plasma processing device according to the first embodiment of the present invention;

FIG. 6 is a sectional view showing the arrangement of the main part of a plasma processing device according to the second embodiment of the present invention;

FIG. 7 is a plan view showing the antenna surface of the RLSA in FIG. 6;

FIG. 8A is a plan view showing an example of the shape and size of a ring member;

FIG. 8B is a sectional view taken along the line VIIIB-VIIIB′ of FIG. 8A;

FIG. 9 is a graph showing the distribution of a plasma density in the plasma processing device according to the second embodiment of the present invention;

FIGS. 10 and 11 are plan views showing modifications of the ring member;

FIGS. 12A and 12B are perspective views showing arrangements of the antenna surface of the RLSA;

FIG. 13 is a view showing the overall arrangement of a conventional high-frequency plasma processing device; and

FIG. 14 is a graph showing the distribution of a plasma density in the conventional plasma processing device.

### DESCRIPTION OF THE PREFERRED EMBODIMENTS

The embodiments of the present invention will be described in detail with reference to the accompanying drawings.

### First Embodiment

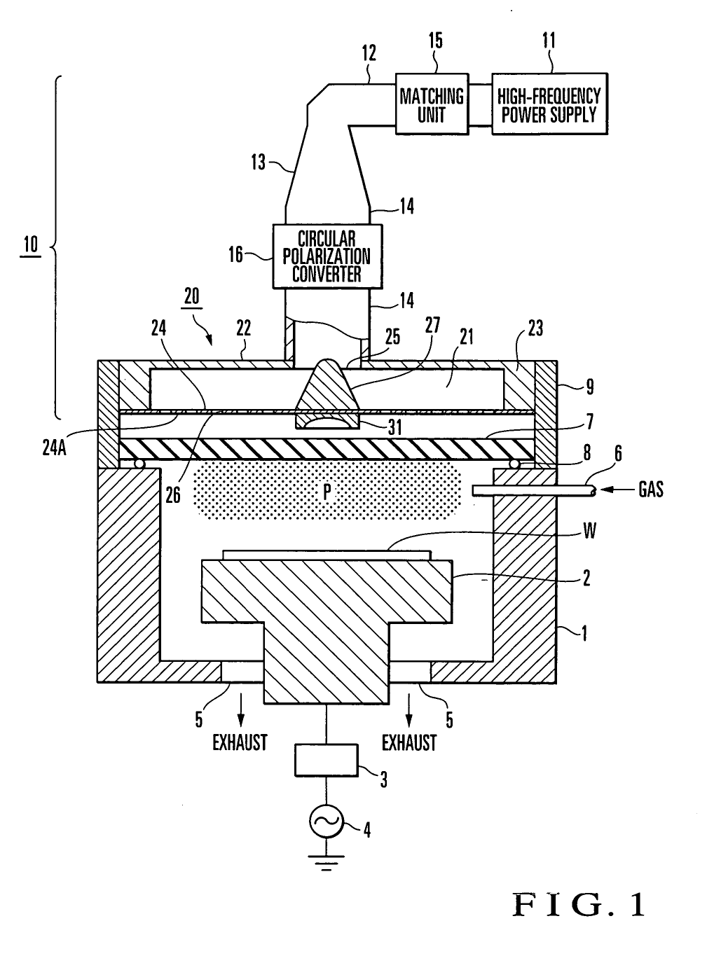

FIG. 1 shows the overall arrangement of a plasma processing device according to the first embodiment of the present invention. The plasma processing device has a bottomed cylindrical processing vessel 1 with an upper opening. A susceptor 2 is accommodated in the processing vessel 1. A substrate W such as a semiconductor, LCD, or organic EL is placed as a target object on the upper surface (stage surface) of the susceptor 2. The susceptor 2 is connected to a high-frequency power supply 4 through a matching box 3.

Exhaust ports 5 for vacuum evacuation are formed in the bottom of the processing vessel 1. A gas introducing nozzle 6 is arranged in the side wall of the processing vessel 1 to introduce a gas into the processing vessel 1. For example, when the plasma processing device is used as an etching device, a plasma gas such as Ar and an etching gas such as CF₄ are introduced into it through the nozzle 6.

The upper opening of the processing vessel 1 is closed with a dielectric plate 7 so, while a high-frequency electromagnetic field is introduced through it, a plasma P generated in the processing vessel 1 does not leak outside. A seal member 8 such as an O-ring is interposed between the upper surface of the side wall of the processing vessel 1 and the lower surface of the periphery of the dielectric plate 7 to ensure the hermeticity in the processing vessel 1.

For example, an RLSA 20 of an electromagnetic field supply device 10 which supplies a high-frequency electromagnetic field into the processing vessel 1 is arranged on the dielectric plate 7. The RLSA 20 is isolated from the interior of the processing vessel 1 by the dielectric plate 7, and is accordingly protected from the plasma P. The outer surfaces of the dielectric plate 7 and RLSA 20 are covered with a shield material 9 arranged annularly on the side wall of the processing vessel 1. Thus, the high-frequency electromagnetic field supplied from the RLSA 20 into the processing vessel 1 will not leak outside.

The electromagnetic field supply device 10 has a high-frequency power supply 11 which generates a high-frequency electromagnetic field having a predetermined frequency within the range of, e.g., 0.9 GHz to ten-odd GHz, the RLSA 20 described above, a rectangular waveguide 12 which connects the high-frequency power supply 11 and RLSA 20 to each other, a rectangular cylindrical converter 13, and a cylindrical waveguide 14. The rectangular waveguide 12 or cylindrical waveguide 14 is provided with a load matching unit 15 which matches the impedance between the power supply and load. The cylindrical waveguide 14 is provided with a circular polarization converter 16 which rotates the high-frequency electromagnetic field in a plane perpendicular to its axis to convert the field into circular polarized waves.

The RLSA 20 has two parallel circular conductor plates 22 and 24 which form a radial waveguide 21, and a conductor ring 23 which connects the edge portions of the two conductor plates 22 and 24 so that they are shielded. An opening 25 to be connected to the cylindrical waveguide 14 is formed at the central portion of the conductor plate 22 serving as the upper surface of the radial waveguide 21. A high-frequency electromagnetic field is introduced into the radial waveguide 21 through the opening 25. A plurality of slots 26, through which the high-frequency electromagnetic field propagating in the radial waveguide 21 is supplied into the processing vessel 1 through the dielectric plate 7, are formed in the circular conductor plate 24 serving as the lower surface of the radial waveguide 21. The slots 26 form the slot antenna. The dielectric plate 7 side surface of the circular conductor plate 24 where the slots 26 are formed will be referred to as the antenna surface of the RLSA 20.

A bump 27 is provided at the central portion of the circular conductor plate 24 serving as the lower surface of the radial waveguide 21 and projects toward the opening 25 of the circular conductor plate 22 serving as the upper surface. The bump 27 is formed to have a substantially circular conical shape, and its distal end is rounded spherically. The bump 27 can be made of either a conductor or dielectric. With the bump 27, a change in impedance from the cylindrical waveguide 14 to the radial waveguide 21 is moderated, and accordingly the reflection of the high-frequency electromagnetic field at the connecting portion of the cylindrical waveguide 14 and radial waveguide 21 is suppressed.

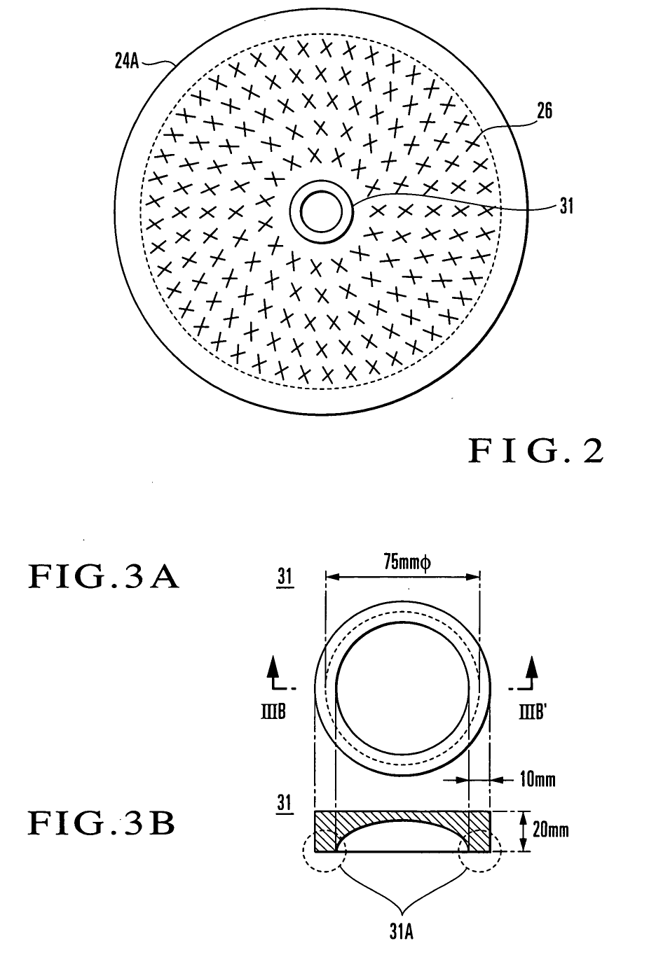

A concave member 31 is provided on an antenna surface 24A of the RLSA 20. FIG. 2 shows the antenna surface 24A of the RLSA 20. The concave member 31 is arranged at that region of the central portion of the antenna surface 24A where no slots 26 are formed.

FIG. 3A shows an example of the shape and size of the concave member 31. The concave member 31 has a shape obtained by hollowing out the lower surface of a short cylinder spherically to leave its periphery. The upper surface of the concave member 31 is fixed to the antenna surface 24A of the RLSA 20. Thus, the periphery of the concave member 31 projects from the antenna surface 24A toward the dielectric plate 7. The periphery of the concave member 31 will be referred to as a projection 31A. When fixing the concave member 31 to the antenna surface 24A, the center of the upper surface of the concave member 31 is substantially aligned with the center of the antenna surface 24A.

The concave member 31 is made of a metal material such as copper or aluminum, and usually of the same material as that of the RLSA 20. The concave member 31 can be entirely made of the metal material, but it suffices as far as its surface is conductive. For example, the core portion of the concave member 31 can be made of an insulating member lighter than a metal, and the surface of the concave member 31 can be covered with a thin metal film, thus forming the concave member 31. Alternatively, the concave member 31 can be a hollow member. When the weight of the concave member 31 is decreased in this manner, the load acting on the antenna surface 24A where the concave member 31 is to be attached can be decreased. Although the concave member 31 is usually connected to the antenna surface 24A electrically, electrical connection need not be made between them.

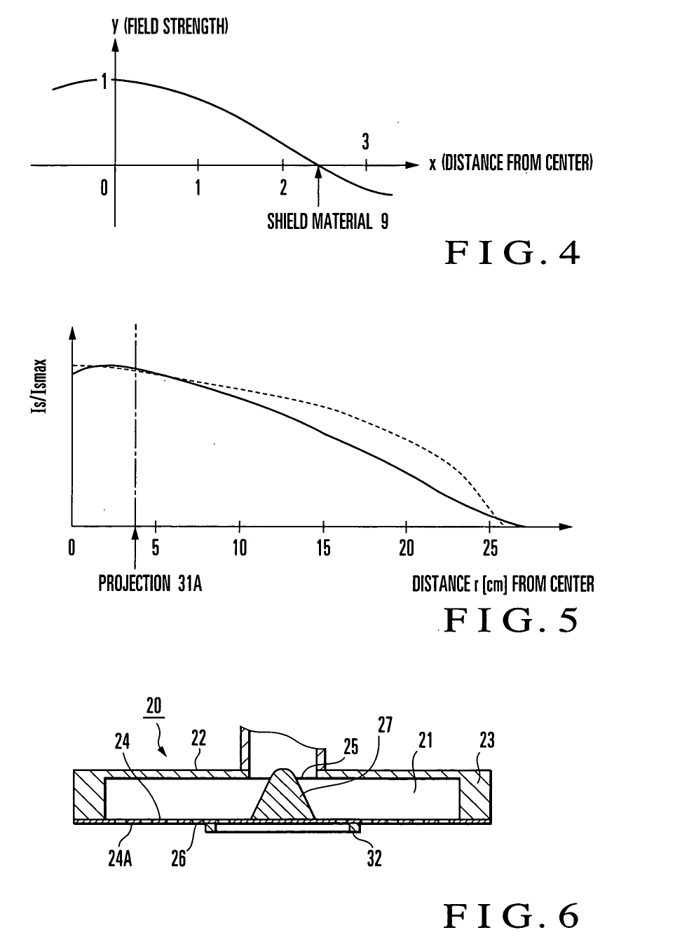

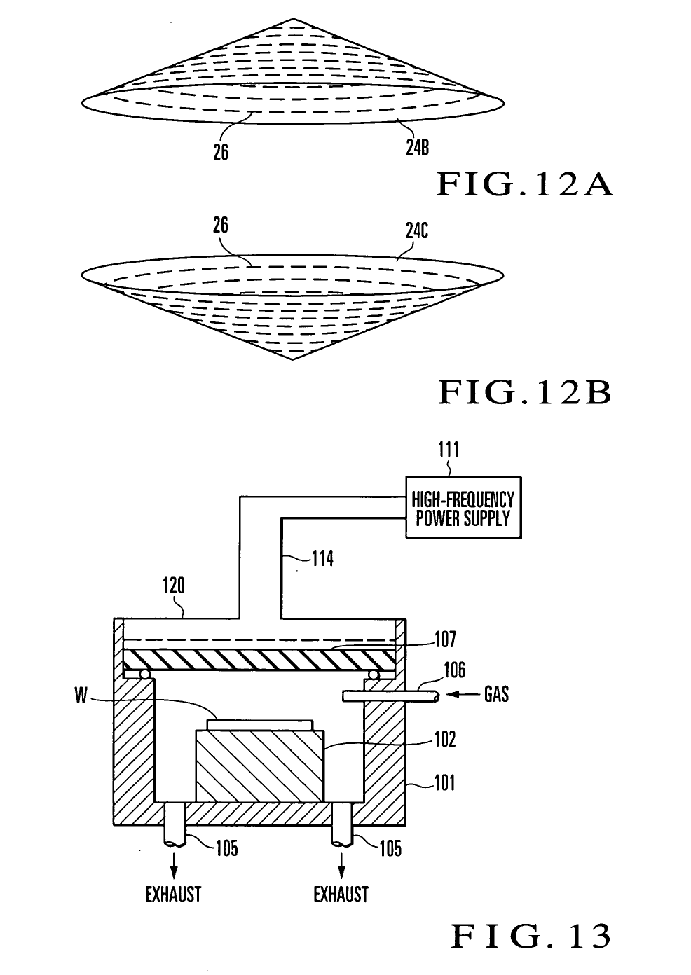

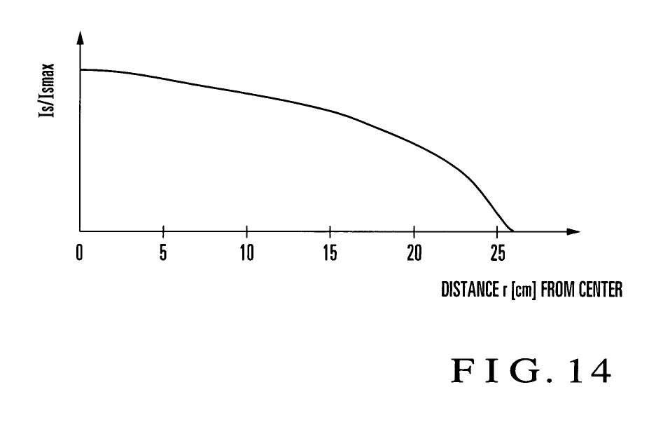

When no concave member 31 is provided, in the space surrounded by the antenna surface 24A of the RLSA 20, the surface of the plasma P generated along the dielectric plate 7, and the shield material 9, the distribution of the field strength is supposed to be based on the Bessel function. FIG. 4 shows 0th-order type-I Bessel function. The x-axis corresponds to the distance from the center within a plane parallel to the surface of the plasma P, and the y-axis corresponds to the field strength. As shown in FIG. 4, the field strength is high at the central portion of the space, and decreases toward the periphery. The higher the field strength, the more the generation of the plasma is promoted. With the conventional plasma processing device shown in FIG. 13, it is supposed that the distribution of the plasma density is large at the central portion and decreases toward the periphery, as shown in FIG. 14.

When the concave member 31 is arranged on the antenna surface 24A of the RLSA 20, the distance between the projection 31A of the concave member 31 and the surface of the plasma P becomes smaller than the distance between the antenna surface 24A and the surface of the plasma P. Consequently, the electric field between the antenna surface 24A and the surface of the plasma P focuses at the position of the projection 31A to increase the field strength. Thus, plasma generation at this position is promoted.

FIG. 5 shows the distribution of the plasma density in the plasma processing device according to this embodiment. The axis of abscissa represents a distance r from the center within a plane parallel to the stage surface of the susceptor 102, and the axis of ordinate represents a value (Is/Ismax) obtained by normalizing a saturation electron current Is at a plasma space potential with its maximal value Ismax. The normalized value is proportional to the plasma density, as described above.

In the measurement, a concave member 31, which can be arranged on that region of the central portion of the antenna surface 24A of the RLSA 20 where no slots 26 are formed, is used. More specifically, the concave member 31 as shown in FIGS. 3A and 3B, which includes the projection 31A and has a diameter (PCD) of 75 mm, a width of 10 mm, and a height of 20 mm is used. The concave member 31 is attached to the central portion of the antenna surface 24A having a diameter of 54 cm. With the pressure in the processing vessel 1 being set to 133 Pa and the supply power being set to 2.5 kW, a plasma P is generated. In FIG. 5, a result obtained by measuring the density of the generated plasma P by the probe method is indicated by a solid line. For comparison, a measurement result obtained when the concave member 31 is not attached is indicated by a broken line.

From FIG. 5, when the concave member 31 is attached to the central portion of the antenna surface 24A, the peak of the plasma density shifts from the center to near the projection 31A of the concave member 31. Therefore, when the concave member 31 having the projection 31A is attached to the antenna surface 24A and the distribution of the field strength between the antenna surface 24A and the surface of the plasma P is controlled, the distribution of the plasma density can be adjusted.

### Second Embodiment

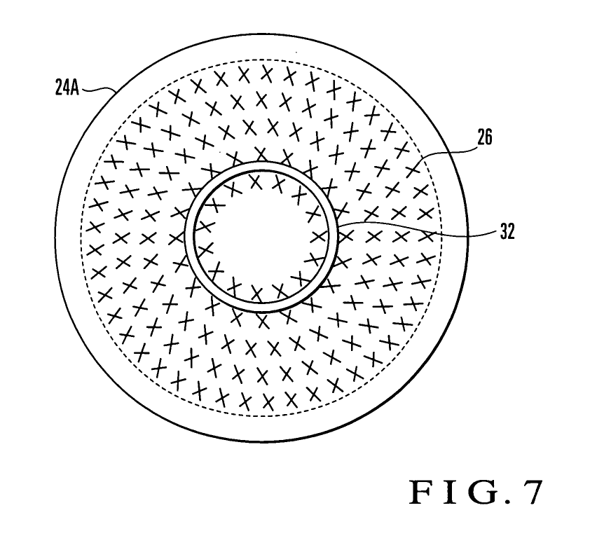

FIG. 6 shows the arrangement of the main part of a plasma processing device according to the second embodiment of the present invention. FIG. 7 shows an antenna surface 24A of an RLSA 20 in FIG. 6. In this embodiment, a ring member 32 having a radius larger than that of the concave member 31 used in the first embodiment is used.

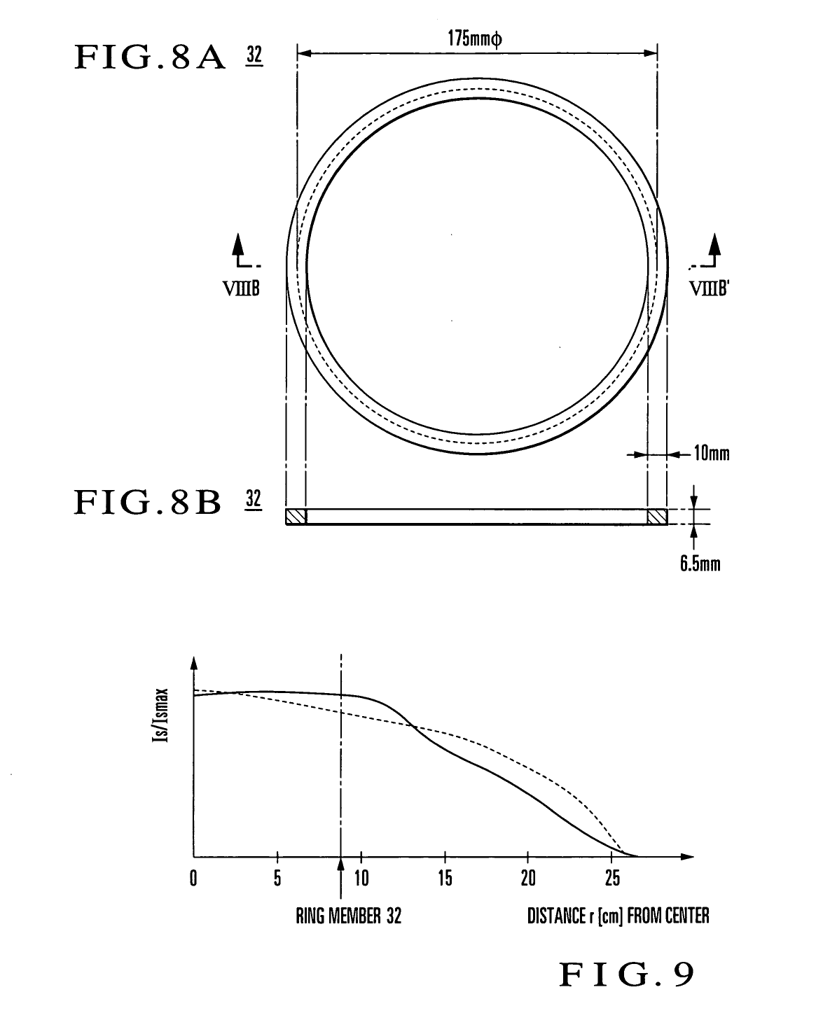

FIG. 8A shows an example of the shape and size of the ring member 32. The ring member 32 is obtained by forming a metal material into a circular ring when seen from the top, and its section has a rectangular shape. The ring member 32 can be entirely made of a metal material, in the same manner as the concave member 31 used in the first embodiment. It suffices as far as the surface of the ring member 32 is conductive.

As shown in FIG. 6, the upper surface of the ring member 32 having the above arrangement is fixed to the antenna surface 24A of the RLSA 20. Accordingly, the ring member 32 projects from the antenna surface 24A toward a dielectric plate 7, so that it serves as a projecting member.

In this case, as shown in FIG. 7, the center of the ring member 32 is substantially aligned with the center of the antenna surface 24A. As the radius of the ring member 32 is larger than that of the concave member 31 used in the first embodiment, the ring member 32 is arranged in that region of the antenna surface 24A where slots 26 are formed. Although the ring member 32 can block the slots 26 partly, it is desirably arranged not to block the slots 26 as much as possible. Alternatively, the ring member 32 is partly notched, so that it will not block the slots 26.

Although the ring member 32 is usually connected to the antenna surface 24A electrically, electrical connection need not be made between them.

FIG. 9 shows the distribution of a plasma density in the plasma processing device according to this embodiment. The axis of abscissa and the axis of ordinate are the same as those of FIG. 5.

In the measurement, a ring member 32 having a diameter (PCD) of 175 mm, a width of 10 mm, and a height of 6.5 mm, as shown in FIG. 8A is used. The ring member 32 is attached to the antenna surface 24A having a diameter of 54 cm. With the pressure in a processing vessel 1 being set to 133 Pa and the supply power being set to 2.5 kW, a plasma P is generated. In FIG. 9, a result obtained by measuring the density of the generated plasma P by the probe method is indicated by a solid line. For comparison, a measurement result obtained when the ring member 32 is not attached is indicated by a broken line.

From FIG. 9, when the ring member 32 is attached to the antenna surface 24A, the distribution of the plasma density becomes flat from the central portion as far as to a position over the ring member 32. Therefore, when the ring member 32 is attached to the antenna surface 24A and the distribution of the field strength between the antenna surface 24A and the surface of the plasma P is controlled, the distribution of the plasma density can be adjusted.

As in this embodiment, when the center of the ring member 32 is aligned with the center of the antenna surface 24A, the distribution of the plasma density which is concentric with respect to the axis of the processing vessel 1 can be adjusted. If the plasma density does not have a circular distribution, as in a case wherein the side wall of the processing vessel 1 forms a polygon, the shape of the ring member 32 may be determined in accordance with the shape of the distribution. This applies to the concave member 31 used in the first embodiment. The outer shape of the concave member 31 may be determined in accordance with the shape of the distribution of the plasma density.

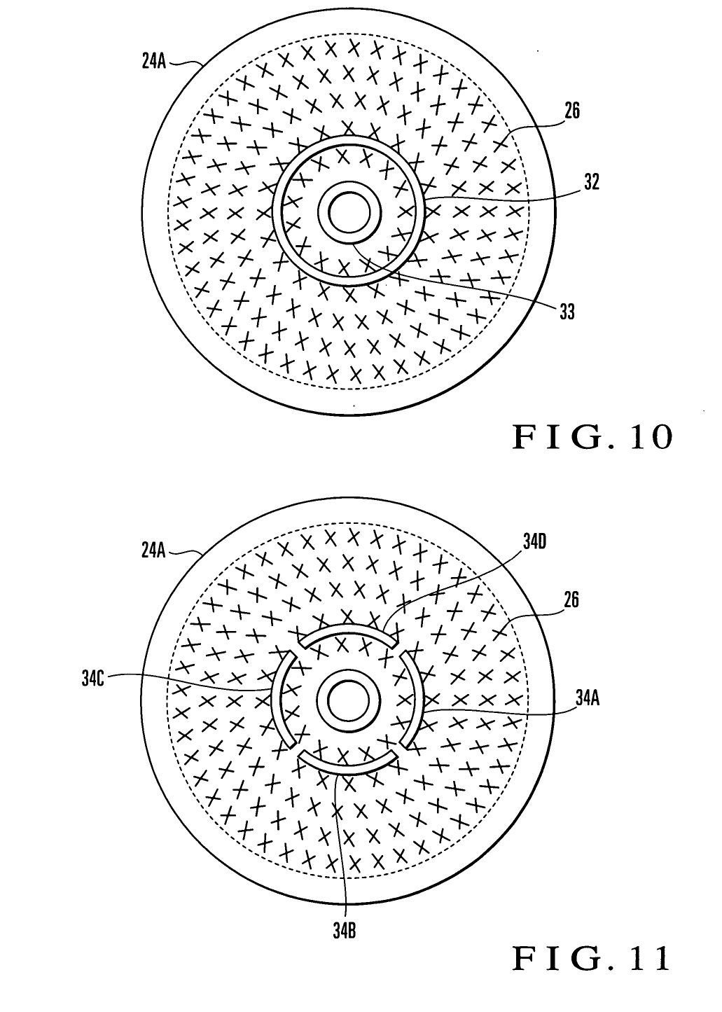

According to a modification of this embodiment, the radius of the ring member 32 may be decreased, and the ring member 32 may be arranged at that region of the central portion of the antenna surface 24A where no slots 26 are formed. As shown in FIG. 10, a plurality of ring members 32 and 33 may be concentrically arranged on the antenna surface 24A. As shown in FIG. 11, several divisional members 34A, 34B, 34C, and 34D which are conductive at least on their surfaces may be arranged to form a ring.

In the first and second embodiments, that side of the concave member 31 or ring member 32 which opposes the dielectric plate 7 forms a convex. Particularly, the lower side of the projection 31A of the concave member 31 or of the ring member 32 has a sharp corner, and an electrical field tends to concentrate there. When this corner is rounded, concentration of the electric field is moderated. Therefore, when the corner of the projection 31A of the concave member 31 or of the ring member 32 is appropriately rounded, the distribution of the field strength is controlled, so that the distribution of the plasma density can be adjusted.

The concave member 31 or ring member 32 can be attached not only to the flat antenna surface 24A as shown in FIGS. 1 and 6, but also to an upward or downward convex circular conical antenna surface 24B or 24C, as shown in FIGS. 12A or 12B.

The concave member 31 or ring member 32 can be attached not only to the antenna surface 24A, 24B, or 24C of the RLSA, but also to the antenna surface of another slot antenna, e.g., a waveguide slot antenna.

The concave member 31 or ring member 32 can be attached to a conductor plate serving as the resonator of a patch antenna.

In the above embodiments, the slot antenna having the antenna surface 24A, 24B, or 24C, the patch antenna, and the like are generally referred to as flat antennas.

The plasma processing device described above can be utilized as an etching device, CVD device, ashing device, or the like.

As has been described, in the above embodiments, a projection which projects from the surface of the antenna toward the dielectric plate is arranged, and accordingly the distance between the distal end of the projection and the plasma surface becomes smaller than the distance between the antenna surface and plasma surface. Consequently, the electric field concentrates at the position of the projection and the field strength increases. The higher the field strength, the more the generation of the plasma is promoted. Therefore, when the projection is arranged at a predetermined position to control the distribution of the field strength, the distribution of the plasma density can be adjusted.

When the projection forms a ring and its center is substantially aligned with the center of that surface of the antenna which opposes the dielectric plate, the distribution of the plasma density which is concentric with respect to the axis of the vessel can be adjusted.

When that side of the projection which opposes the dielectric plate forms a convex, the electric field readily focuses on it. Thus, adjustment of the plasma distribution can be facilitated.

1. A plasma processing device comprising:
a susceptor having a stage surface on which a target object is to be arranged;
a vessel which accommodates said susceptor and has an opening in a side which opposes said stage surface of said susceptor;
a dielectric plate which closes the opening of said vessel;
an antenna which supplies a high-frequency electromagnetic field into said vessel through said dielectric plate; and
a projection which projects from a surface of said antenna which opposes said dielectric plate toward said dielectric plate, at least the surface of said projection being conductive.

2. A device according to claim 1, wherein said projection is arranged to form a ring such that a center thereof is aligned with a center of said surface of said antenna which opposes said dielectric plate.

3. A device according to claim 2, wherein said projection includes a plurality of projections.

4. A device according to claim 2, wherein said projection is divided into several members, and said several members are arranged to form a ring.

5. A device according to claim 1, wherein a side of said projection which opposes said dielectric plate forms a convex.

6. A device according to claim 1, wherein said antenna is a slot antenna having a slot formed in a surface which opposes said dielectric plate.

7. A plasma processing method comprising the steps of:
arranging a target object in a vessel;
supplying a high-frequency electromagnetic field with an antenna into the vessel from outside through a dielectric plate which closes an opening of the vessel, thus generating a plasma in the vessel, the antenna including a projection which projects from a surface thereof toward the dielectric plate, and the projection being conductive at least on a surface thereof; and
subjecting the target object to a predetermined process with the plasma.
